(19) United States
(12) Patent Application Publication
(10) Pub. No.: US 2011/0277821 A1
(43) Pub. Date: Nov. 17, 2011

(54) BACK-SHEET MATERIAL FOR PHOTOVOLTAIC MODULE

(75) Inventor: Stephen Yau-Sang CHENG, Hong Kong (HK)

(73) Assignee: Du Pont Apollo Limited, Hong Kong (HK)

(21) Appl. No.: 13/102,064

(22) Filed: May 6, 2011

Related U.S. Application Data
(60) Provisional application No. 61/333,674, filed on May 11, 2010.

(51) Int. Cl. H01L 31/048; B32B 37/12; B32B 3/00; B32B 37/02; B32B 11/00; B32B 27/36

(52) U.S. Cl. 136/251; 428/489; 428/480; 428/468; 428/332; 156/60

(57) ABSTRACT

Disclosed herein is a back sheet for a photovoltaic module. The back sheet includes a dielectric layer, an adhesive layer disposed on the dielectric layer, a barrier layer disposed on the adhesive layer and a weather resistant layer disposed on the barrier layer. The weather resistant layer includes a bituminous material.

### RELATED APPLICATIONS

This application claims priority to U.S. Provisional Application Ser. No. 61/333,674, filed May 11, 2010, which is herein incorporated by reference.

### BACKGROUND

1. Field of Invention

The present invention relates to a photovoltaic module (PV module). More particularly, the present invention relates to a PV module having a back sheet comprising a bituminous material.

2. Description of Related Art

PV modules are units capable of converting light energy into electrical energy. PV modules are commonly manufactured in the form of laminated structures including at least a solar cell string and an encapsulating system. The solar cell string consists of a plurality of solar cells, whereas the encapsulating system includes front and back protective sheets and a polymeric material. The solar cells are encapsulated by the polymeric material and disposed between the front and back sheets with the polymeric material bonded to the front and back protective sheets. Such laminated structure may mechanically support the fragile silicon cells and also protect the cells/modules against environmental degradation.

PV modules used in outdoor solar farms or rooftops are required to withstand the environment through the operating lifetime, and increased lifetime of PV modules is of upmost interest to the industry to reduce the cost of solar electricity. Besides the solar cell string itself, the encapsulating system is the component with the highest responsibility for the lifetime of a PV module. Generally, the primary functions of the back sheet include vapor/moisture barrier, UV resistance, electrical insulation, mechanical support and protection, and resistance to weathering.

Conventional back sheets are laminate having a weather resistant layer. Fluorinated polymers are known to be highly resistant to UV radiation and widely used as the weather resistant layer. However, the fluorinated polymers are quite expensive thus increasing the manufacturing cost of PV modules.

Accordingly, there exists a need in the art for providing a durable and low-cost material to serve as the weather resistant layer for a PV module.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one aspect, the present invention is directed to a back sheet for a photovoltaic module. The back sheet has a weather resistant layer comprising a bituminous material instead of the fluorinated polymer used in the conventional art. The bituminous material offers durable protection against weathering at a lower cost than the fluorinated polymer. In addition, the bituminous material can be formulated to adhere to the adjacent layer without the use of an additional adhesive, as exemplified by commercially available bitumen coatings such as UNIFLEX 500® which can be applied directly to aluminum roofing according to company information, thereby reducing the manufacturing time and cost of the back sheet.

In one embodiment of the present invention, the back sheet comprises a dielectric layer; an adhesive layer disposed on the dielectric layer; a barrier to layer disposed on the adhesive layer; and a weather resistant layer comprising a bituminous material disposed on the barrier layer.

In another aspect, the present invention is directed to a photovoltaic module. The photovoltaic module includes a back sheet according to the aspect and embodiment(s) of the present invention, and hence, is protected is from weathering.

In yet another aspect, the present invention is directed to a process for manufacturing a back sheet for a photovoltaic module. According to this method, a bituminous material, rather than a fluorinated polymer, is used as the weather resistant layer.

According to one embodiment of the present invention, the process comprises the steps as follows. A polyester dielectric layer is provided and an adhesive layer is applied over the polyester dielectric layer. A metal barrier layer is applied over the adhesive layer thereby bonding the metal barrier layer to the polyester dielectric layer. A bituminous layer is applied over the metal barrier layer. As such, a laminated back sheet for a photovoltaic module is obtained.

Many of the attendant features will be more readily appreciated as the same becomes better understood by reference to the following detailed description considered in connection with the accompanying drawings.

### BRIEF DESCRIPTION OF THE DRAWINGS

The present description will be better understood from the following detailed description read in light of the accompanying drawing, wherein:

FIG. 1 is a schematic diagram illustrating the back sheet according to one embodiment of the present invention.

FIG. 2 is a schematic diagram illustrating the photovoltaic module according to one embodiment of the present invention.

### DETAILED DESCRIPTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

References in the singular may also include the plural (for example, “a” and “an” may refer to one, or one or more) unless the context specifically states otherwise. The use of numerical values in the various ranges specified in this application, unless expressly indicated otherwise, are stated as approximations as though the minimum and maximum values within the stated ranges were both preceded by the word “about”. In this manner, slight variations above and below the stated ranges can be used to achieve substantially the same results as values within the ranges. Also, the disclosure of these ranges is intended as a continuous range including every value between the minimum and maximum values.

Preferably, PV modules used in outdoor should have an operating lifetime of more than 20 years or more. To this end, a weather resistant layer is usually adopted in the back sheet of the PV module to protect the PV modules from weathering factors such as UV exposure, moisture condensation and air/oxygen permeation. One of the leading materials for the weather resistant layer is fluorinated polymer, such as TEDLAR® (the trade name for a polyvinyl fluoride polymer manufactured by E. I. du Pont de Nemours and Company (DuPont)). However, as discussed in the description of the related art, such fluorinated polymer is quite expensive.

In seeking an alternative material for the weather resistant layer, the present inventor's attention was attracted to bitumen. Bitumen is a general term for the group of oil and tar products obtained by refining crude oil. Bitumen is the world's most widely used binder for road paving. In addition, bitumen is also used as the adhesive for laying roof tiles.

Hence, in one aspect, the present invention is directed to apply a bituminous material to the PV module in place of the conventional fluorinated polymeric layer as the weather resistant layer. In this aspect of the present invention, the bituminous material can be used as a weather resistant coating in addition to as an adhesive. As such, the manufacturing cost and time of the back sheet can be reduced.

For the purpose of the present invention, the term “bituminous material” means a bitumen-containing material. Also, the terms “bituminous material” and “bitumen”, as used throughout this specification may be replaced with the term “asphalt” which substantially means petroleum asphalt.

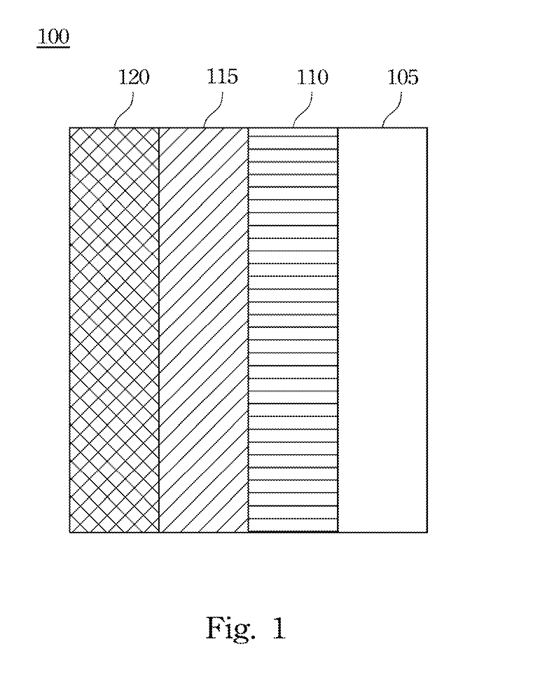

According to the present invention, the back sheet has multiple layers laminated together. Referring now to FIG. 1, the back sheet 100 according to one embodiment of the present invention comprises: a dielectric layer 105, an icy adhesive layer 110, a barrier layer 115 and a weather resistant layer 120. The adhesive layer 110 is disposed between the dielectric layer 105 and barrier layer 115 whereby one surface of the barrier layer 115 is bonded to the dielectric layer 105. The weather resistant layer 120 comprises a bituminous material and is disposed on the other surface (that is, the surface opposing to the one bonding to the dielectric layer 105) of the barrier layer 115.

According to the embodiments of the present invention, the dielectric layer 105 may be made from any material which acts as an electrical insulator, and is preferably a polymeric dielectric layer.

One example of the polymeric dielectric layer is the polyester. Examples of polyester include, but are not limited to: polyethylene terephthalate, polybutylene terephthalate, polyethylene naphthalate and styrene-polyester copolymer.

Optionally, the polyester dielectric layer may be an oriented polyester film, such as a bi-axially-oriented polyester film. Other illustrative examples of the polymer for forming the polymeric dielectric layer may include polycarbonate, cyclic polyolefins, polyamides, polyurethanes, acrylics, polyacrylate, metallocene-catalyzed and the like.

In accordance with the present invention, the adhesive layer 110 may comprise any material that is suitable to bond the barrier layer 115 to the dielectric layer 105. Examples of such material include, but are not limited to amino-functional silanes, glycidoxy-functional silanes, poly(ally amines), and poly(vinyl amines).

The barrier layer 115 used herein may serve as a moisture and/or oxygen barrier layer. In one example, the barrier layer is a metal foil. Alternatively, the barrier may be formed of a metal oxide; still alternatively, the barrier layer may be a polymeric layer.

The metal foil may, for example, be made of steel, copper, aluminum or alloy thereof. Optionally, the metal foil may be galvanized thereby providing better corrosion resistance.

Alternatively, the surface of the metal foil may be optionally subjected to a surface finishing treatment with chromates or phosphates in light of preventing dissolution and corrosion. The metal foil may also be optionally primed with polymeric material(s), such as ethylene acrylic acid copolymers or ethylene maleic anhydride copolymers, to improve its adhesion to other polymeric materials.

Also, layers of metal oxides such as aluminum oxide and silicon oxide may prevent the permeation of moisture/water vapor, and hence can be used as the barrier layer 115 of the present invention.

Illustrative examples of the polymer that may be used to form the barrier layer 115 include, but are not limited to: parylene, polyimide, polyacrylamide, epoxy, polystyrene, poly(vinyl alcohol), poly(vinylidene chloride), poly(vinyl chloride), polyvinylidene fluoride, and acrylonitrile.

According to the principle and spirits of the present invention, the bituminous material used to form the weather resistant layer 120 may be an unmodified bitumen composition or a modified bitumen composition.

As used herein, the term “unmodified bitumen composition” means ordinary bitumen that is not chemically or physically modified by a modifier, whereas the term “modified bitumen composition” signifies a bitumen material which has incorporated in it a modifier to improve the elongation, flexibility, temperature susceptibility, and adhesive properties of the ordinary bitumen.

One well known class of modifiers is thermoplastic elastomers or thermoplastic rubbers. These modifiers include, but are not limited to, styrene-butadiene-styrene (SBS), styrene-isoprene-styrene (SIS), and styrene-ethylene-butylene-styrene (SEBS). These agents may simply be blended into the bitumen. Another class of modifier which can be used in the present invention to impart the desired properties to the bituminous material is polyurethane.

Other examples of modifier include, but are not limited to: ethylene vinyl acetate, polyvinyl toluene, polypropylene-ethylene copolymers, polyethylene, polyoxyethylene, atactic polypropylene, isotactic polypropylene, thermoplastic polyolefin, amorphous polyalphaolefin and polychloroprene.

Generally, the bitumen remains the major component in a modified bitumen composition. In one embodiment, the modified bitumen composition may comprise about 20-99 wt % of the bitumen; preferably about 40-95 wt %; and more preferably about 60-90 wt %.

Specifically, modified bitumen composition may comprises about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98 or 99 wt % of the bitumen.

Optionally, the weather resistant layer 120 used herein may further comprises a pigment in addition to the bituminous material. In addition to enhance the aesthetic appearance of the PV module using the back sheet 100, the pigment may also provide the weather resistant layer with improved reflectivity whereby enhancing the conversion efficiency of the PV module.

Examples of pigment that can be employed in the present invention include, but are not limited to: titanium dioxide, calcium carbonate, colemanite, aluminum trihydride (ATH), borate compounds, and mixtures thereof. Titanium dioxide, for example, may produce a white color in the weather resistant layer 120. The coating can be formulated in a variety of colors to conform to building aesthetics.

According to the embodiments of the present invention, the weather resistant layer 120 may have a thickness of at least 10-2000 micron. For example, the thickness of the weather resistant layer 120 may be about 10-1000 micron; preferably about 25-500 micron; and more preferably about 25-100 micron.

Specifically, the thickness of the weather resistant layer 120 may be about 10, 15, 20, 25, 30, 35, 40, 45, 50, 55, 60, 65, 70, 75, 80, 85, 90, 95, 100, 150, 200, 250, 300, 350, 400, 450, 500, 550, 600, 650, 700, 750, 800, 850, 900, 950, 1000, 1050, 1100, 1150, 1200, 1250, 1300, 1350, 1400, 1450, 1500, 1550, 1600, 1650, 1700, 1750, 1800, 1850, 1900, 1950 or 2000 micron.

In another aspect, the present invention is directed to a photovoltaic module comprising a back sheet according to the above-described aspect/embodiments of the present invention. The back sheet can, for example, be the one shown in FIG. 1.

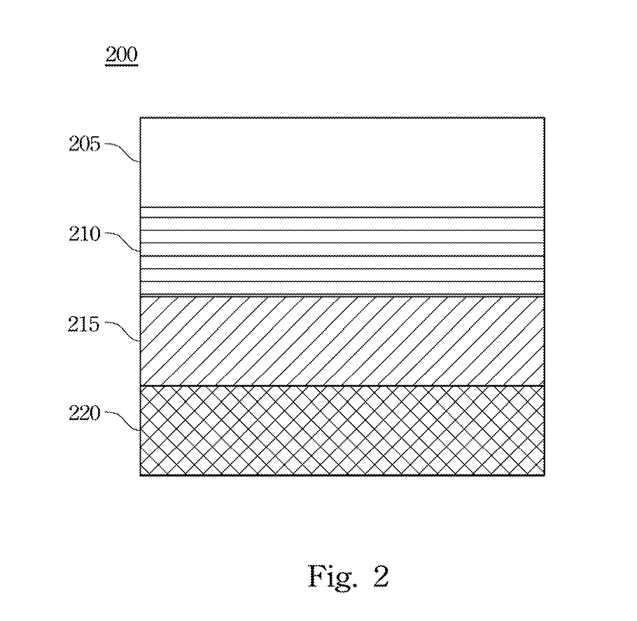

Referring now to FIG. 2, the photovoltaic module 200 according to one embodiment of the present invention may include at least four structural layers in the following order, from top to bottom: a front sheet 205, a solar cell stack film 210, an encapsulant sheet 215, and a back sheet 220 of the present invention.

The front sheet 205 is the layer first contacted by light and is formed of a light-transmitting material.

The encapsulant sheet 215 encapsulates the solar cell(s) in the solar layer. The encapsulant sheet may be respectively formed of at least one polymeric material, such as, acid copolymers, ethylene (meth)acrylic acid copolymer, ionomers, ethylene vinyl acetate (EVA), acoustic poly(vinyl acetal), acoustic poly(vinyl butyral), polyvinylbutyral (PVB), thermoplastic polyurethane (TPU), polyvinylchloride (PVC), metallocene-catalyzed linear low density polyethylenes, polyolefin block elastomers, ethylene acrylate ester copolymers (e.g., poly(ethylene-co-methyl acrylate) and poly(ethylene-co-butyl acrylate)), silicone elastomers, epoxy resins and combinations thereof.

The solar cell stack film 210 may comprise one or more electrically interconnected solar cells. Within the scope of the present invention, a solar cell is meant to include any article which can convert light into electrical energy. Generally, solar cells can be categorized into crystalline solar cells and thin film solar cells. The photovoltaic material used in crystalline solar cells may be monocrystalline silicon, polycrystalline silicon or microcrystalline silicon.

Thin film solar cells are produced by depositing one or more thin layers of photovoltaic material on a substrate. Many different photovoltaic materials are deposited with various deposition methods on a variety of substrate. Thin-film solar cells are usually categorized according to the photovoltaic material used: amorphous silicon (a-Si) and other thin-film silicon, copper indium selenide (CIS), cadmium telluride (CdTe), and dye sensitized solar cells (DSC) and other organic solar cells.

In one embodiment of the present invention, the weather resistant layer of the back sheet 220 for use in the photovoltaic module comprises a modified bitumen composition. Besides, the thickness of such weather resistant layer is about 25-100 micron.

In yet another aspect, the present invention is directed to a process for manufacturing a back sheet for a photovoltaic module. According to this method, a bituminous material, rather than a fluorinated polymer, is used as the weather resistant layer.

According to one embodiment of the present invention, the process comprises the steps as follows. A polyester dielectric layer is provided and an adhesive layer is applied over the polyester dielectric layer. A metal barrier layer is applied over the adhesive layer thereby bonding the metal barrier layer to the polyester dielectric layer. A bituminous layer is applied over the metal barrier layer. As such, a laminated back sheet for a photovoltaic module is obtained.

The polyester dielectric layer can be any one of the polyester dielectric layers described hereinabove in connection with dielectric layer 105. Specifically, the polyester dielectric layer can be made of polyethylene terephthalate, polybutylene terephthalate, polyethylene naphthalate or styrene-polyester copolymer.

Optionally, the polyester dielectric layer may be an oriented polyester film, such as a bi-axially-oriented polyester film. Similarly, the material of the adhesive layer can be any one of those described in connection with adhesive layer 110.

The metal barrier layer can be a metal foil made of steel, copper, aluminum or alloy thereof. In one optional embodiment, the process may further include a step of galvanizing the surface of the metal barrier layer.

Alternatively, in another optional embodiment, the process may further include a surface finishing treatment, wherein the surface of the metal barrier layer is treated with chromates or phosphates.

In another optional embodiment, the process further include a priming step, wherein the surface of the metal barrier layer is primed with polymeric material(s), such as ethylene acrylic acid copolymers or ethylene maleic anhydride copolymers, to improve its adhesion to other polymeric materials, such as the adhesive layer and/or the bituminous layer.

According to embodiments of the present invention, the bituminous layer used herein may be an unmodified bitumen composition or a modified bitumen composition.

The modified bitumen composition may comprise bitumen in an amount of about 20-99 wt % and at least one modifier in an amount of about 1-80 wt %. The modifier can be any one of the modifiers described hereinabove.

In one embodiment, the bituminous layer may have a thickness of about 25 to 100 micron. For example, the thickness of the bituminous layer is about 25, 30, 35, 40, 45, 50, 55, 60, 65, 70, 75, 80, 85, 90, 95 or 100 micron.

According to embodiments of the present invention, the bituminous layer can be applied in a form of film, sheet, dispersion or melt.

It should be noted that the bituminous material in the bituminous layer is thermoplastic in nature, and hence in one preferable embodiment, the bituminous layer can be applied directly onto metal barrier layer and adheres thereto, without the use of an additional adhesive. As such, the manufacturing time and cost can be reduced.

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of this invention.

What is claimed is:

1. A back sheet for a photovoltaic module, comprising:
a dielectric layer;
an adhesive layer disposed on the dielectric layer;
a barrier layer disposed on the adhesive layer; and
a weather resistant layer comprising a bituminous material disposed on the barrier layer.

2. The back sheet of claim 1, wherein the dielectric layer is a polyester dielectric layer.

3. The back sheet of claim 2, wherein the polyester dielectric layer comprises a material selected from the group consisting of: polyethylene terephthalate, polybutylene terephthalate, polyethylene naphthalate, and styrene-polyester copolymer.

4. The back sheet of claim 1, wherein the barrier layer is a metal foil.

5. The back sheet of claim 4, wherein the metal foil comprises a material selected from the group consisting of steel, copper, aluminum and alloy thereof.

6. The back sheet of claim 1, wherein the barrier layer is a polymeric layer.

7. The back sheet of claim 6, wherein the polymeric layer comprises a material selected from the group consisting of parylene, polyimide, polyacrylamide, epoxy, polystyrene, poly(vinyl alcohol), poly(vinylidene chloride), poly(vinyl chloride), polyvinylidene fluoride, and acrylonitrile.

8. The back sheet of claim 1, wherein the bituminous material is a modified bitumen composition.

9. The back sheet of claim 8, wherein the modified bitumen composition comprises a bitumen and a modifier selected from the group consisting of ethylene vinyl acetate, polyvinyl toluene, polypropylene-ethylene copolymers, polyethylene, polyoxyethylene, polyurethane, styrene-butadiene-styrene block copolymer, styrene-ethylene-butadiene-styrene block copolymer, styrene-isoprene-styrene block copolymer, atactic polypropylene, isotactic polypropylene, thermoplastic polyolefin, amorphous polyalphaolefin and polychloroprene.

10. The back sheet of claim 9, wherein the modified bitumen composition comprises about 20-99 wt % of the bitumen.

11. The back sheet of claim 1, wherein the weather resistant layer further comprises a pigment.

12. The back sheet of claim 11, wherein the pigment is titanium dioxide, calcium carbonate, colemanite, aluminum trihydride (ATH), borate compounds or a mixture thereof.

13. The back sheet of claim 1, wherein the weather resistant layer has a thickness of 10-2000 micron.

14. A photovoltaic module, comprising a back sheet, wherein the back sheet comprises:
a dielectric layer;
an adhesive layer disposed on the dielectric layer;
a barrier layer disposed on the adhesive layer; and
a weather resistant layer comprising a bituminous material disposed on the barrier layer.

15. The photovoltaic module of claim 14, further comprising, from top to bottom:
a front sheet;
a solar cell stack film comprising a solar cell; and
an encapsulant sheet which is adjacent to the back sheet.

16. The photovoltaic module of claim 15, wherein the solar cell is a crystalline silicon solar cell or a thin film solar cell.

17. The photovoltaic module of claim 14, wherein the bituminous material is a modified bitumen composition, and the weather resistant layer has a thickness of 10-2000 micron.

18. A process for manufacturing a back sheet for a photovoltaic module, comprising the steps of:
providing a polyester dielectric layer;
applying an adhesive layer over the polyester dielectric layer;
applying a metal barrier layer over the adhesive layer whereby the metal barrier layer is bonded to the polyester dielectric layer; and
applying a bituminous layer over the metal barrier layer.

19. The process of claim 18, wherein the bituminous layer comprises about 20-99 wt % of a bitumen and about 1-80 wt % of a modifier, and the bituminous layer has a thickness of about 25 to 100 micron.

20. The process of claim 18, wherein the bituminous layer is applied in a form of film, sheet, dispersion or melt.
